(19) United States
(12) Patent Application Publication
(10) Pub. No.: US 2009/0042388 A1
(43) Pub. Date: Feb. 12, 2009

(54) METHOD OF CLEANING A SEMICONDUCTOR SUBSTRATE

(76) Inventors: Zhi-Qiang Sun, Singapore (SG); Tien-Cheng Lan, Taipei Hsien (TW); Hua-Kuo Lee, Taipei City (TW); Jing-Hao Chen, Singapore (SG); Wen-Chun Huang, Hsinchu City (TW); Run-Shun Wang, Singapore (SG); Jing-Ling Wang, Singapore (SG); Da-Jiang Yang, Singapore (SG); Chee-Siang Ong, Singapore (SG)

Correspondence Address: NORTH AMERICA INTELLECTUAL PROPERTY CORPORATION, P.O. BOX 506, MERRIFIELD, VA, 22116, US

(21) Appl. No.: 11/836,782

(22) Filed: Aug. 10, 2007

(51) Int. Cl. H01L 21/302

(52) U.S. Cl. 438/689; 257/E21.214

(57) ABSTRACT

A semiconductor substrate is first provided. The semiconductor substrate includes a material layer and a patterned photoresist layer disposed on the material layer. Subsequently, a contact etching process is performed on the material layer by utilizing the patterned photoresist layer as an etching mask so to form an etched hole in the material layer. Thereafter, a solvent cleaning process is carried out on the semiconductor substrate by utilizing a cleaning solvent. Next, a water cleaning process is performed on the semiconductor substrate by utilizing deionized water. The temperature of the deionized water is in a range from 30° C. to 99° C.

### BACKGROUND OF THE INVENTION

1. Field of the Invention

The present invention relates to a cleaning method, and more particularly, to a method of cleaning a semiconductor substrate by using a water cleaning process.

2. Description of the Prior Art

During the fabrication of integrated circuits, lithography technology and etching technology are used to transfer patterns onto each of the appropriate layers in a wafer. For example, in the process of forming a contact plug, portions of a dielectric material layer that are not covered by a photoresist layer are removed, and then the photoresist layer is stripped off. Next, the formed plug hole is filled with a predetermined metal material layer for completing the fabrication of the contact plug.

Please refer to FIG. 1, which is a schematic flow chart illustrating a conventional method of forming a plug. The conventional method includes the following steps:

Step 101: Providing a wafer, and the wafer includes a dielectric material layer;

Step 103: Forming a photoresist layer on the dielectric material layer, and performing a lithography process on the photoresist layer so as to form a predetermined pattern onto the photoresist layer;

Step 105: Removing the unexposed parts of the photoresist layer, and thereby forming a patterned photoresist layer on the wafer;

Step 107: Performing an etching process, such as a plasma etching process or a reactive ion etching (RIE) technology, on the wafer, in which a pattern of the patterned photoresist layer is transferred to the dielectric material layer located underneath for forming a required plug hole in the dielectric material layer;

Step 109: Performing an oxygen plasma ashing process to remove the patterned photoresist layer;

Step 111: Performing a solvent cleaning process, in which the solvent cleaning process utilizes a high temperature solvent for cleaning, such as a hydroxylamine-containing solvent at 70 degrees centigrade (70° C.), to remove the polymers and residues disposed on the surface of the dielectric material layer, on the sidewall of the plug hole, and on the bottom of the plug hole;

Step 113: Further removing the polymers and the cleaning solvent disposed on the dielectric material layer by utilizing the deionized water (D1 water) having a temperature of 25° C.;

Step 115: Forming a barrier layer on the surface of the wafer, and the barrier layer covering the surface of the dielectric material layer, the sidewall of the plug hole, and the bottom of the plug hole;

Step 117: Forming a metal layer on the surface of the wafer, in which the metal layer covers the barrier layer, and the plug hole is filled with the metal layer; and

Step 119: Performing a polishing process to remove the excessive parts of the barrier layer and of the metal layer, so as to form a plug in the dielectric material layer.

The plasma etching process or reactive ion etching process produces undesirable by-products which are difficult to remove from the interaction of the plasma gases, reacted species, and the photoresist. The composition of such by-products is generally made up of the etched substrates, the material layer on the substrate, the photoresist, and the etching gases. The formation of such by-products can be influenced by the type of etching apparatus, the processing conditions, and the types of the etched materials that are utilized. These by-products are generally referred to as “sidewall polymer”; and they cannot be removed completely by using the oxygen plasma ashing process.

Product yield is usually greatly influenced by the cleanliness class of the wafer surface. If etching residues are not removed from the substrate, the residues can interfere with subsequent processes involving the substrate. Thus for ensuring and maintaining the subsequent product quality being unaffected, these residues and by-products should be removed from the wafer surface before the barrier layer is deposited, but at the same time, the formed metal circuits or the semiconductor devices should not be affected. As a result, the wafer is to be transferred to a semiconductor chemical wet station for cleaning by using hydroxylamine solvent at 70° C., and followed by cleaning using deionized water at 25° C. after the oxygen plasma ashing process. Next, subsequent processes are carried out on the wafer.

However, the yield results as measured in the final product quality inspection tests may be inferior to the expected yield. According to the product quality test results, the wafers which are processed by different apparatuses or the wafers processed in different batch under one apparatus may also have different yields, even if the processes performed in the these apparatuses have the same process parameters. For example, the wafers processed by a certain apparatus might have more structural defects. As the industry progresses into submicron processing techniques, the variability in the product yields become larger, and these structural defects usually occur in chips positioned near the edge bevels of the wafers.

According to the data from a plurality of experiments, the yields are mainly affected by having a cleaning solvent residue from the solvent cleaning process. The solvent cleaning process is an opening process. In other words, the evaporable components in the cleaning solvent is to gradually vaporize during the cleaning process. As a result, the viscosity of the cleaning solvent becomes gradually larger and larger during the cleaning process, and the concentration of the cleaning solvent is slowly changed. When the solvent cleaning process takes a longer time, a larger amount of cleaning solvent is more easily attached to the sidewall and bottom of the plug hole, and the surface of the wall, thus making it more difficult for removing the cleaning solvent residue. The cleaning solvent residue usually cannot be detected by a wafer acceptance testing (WAT) or from a cross-sectional inspection of the wafer structure in-situ. However, the existence of the cleaning solvent indeed causes damage to the electrical connection between the metal layer and the underlying device, thereby leading to excessive junction resistance between the metal layer and the underlying device, or the electrical connection failures between the metal layer and the underlying device. The subsequently-formed structures or processes may be further affected by the cleaning solvent residues.

However, if the wafer is washed by the deionized water having a temperature of 25° C. for a long time to remove the cleaning solvent residues, the metal layer positioned at the bottom of the plug hole is etched and is damaged due to a reaction between the deionized water and the cleaning solvent. In order to reduce the amount of the cleaning solvent residues, the frequency for changing the cleaning solvent must be increased for the apparatus which has a lower product yield. In other words, in order to prevent the situation in which the cleaning solvent has an excessive viscosity, the period for each changing cycle of the cleaning solvent must be decreased. The period for changing the cleaning solvent should be shortened from 12 hours to 8 hours. It not only increases the processing time, but also increases the cost for the cleaning solvent. In addition, the improvement in the product yield due to the changing of the cleaning solvent is limited. As a result, the conventional method not only causes a lower yield, but also consumes a higher cost and a larger amount of time.

### SUMMARY OF THE INVENTION

It is therefore the primary object of the present invention to provide a method of cleaning a semiconductor substrate, and a deionized water at high temperature is utilized for removing the cleaning solvent residue on the semiconductor substrate for a shorter period of time, so that the product yield can be increased.

From one aspect of the present invention, the present invention provides a method of cleaning a semiconductor substrate. First, a semiconductor substrate is provided. The semiconductor substrate includes a material layer and a patterned photoresist layer disposed on the material layer. Thereafter, the material layer is etched by utilizing the patterned photoresist layer as an etching mask, so as to form an etched hole in the material layer. Next, a solvent cleaning process is performed on the semiconductor substrate by utilizing a cleaning solvent. Afterwards, a water cleaning process is performed on the semiconductor substrate by utilizing the deionized water. The temperature of the deionized water is in the range from 30° C. to 99° C., and the reaction time of the water cleaning process is in the range from 30 seconds to 5 minutes.

From another aspect of the present invention, the present invention further provides another method of cleaning a semiconductor substrate. First, a semiconductor substrate is provided. The semiconductor substrate includes a material layer. Subsequently, a solvent cleaning process is performed on the semiconductor substrate and the material layer by utilizing a cleaning solvent. The cleaning solvent contains hydroxylamine. Next, a water cleaning process is performed on the semiconductor substrate by utilizing the deionized water, where the temperature of the deionized water is in the range from 30° C. to 99° C., and the reaction time of the water cleaning process is in the range from 30 seconds to 5 minutes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic flow chart illustrating a conventional method of forming a plug;

FIGS. 2-8 are a plurality of schematic cross-sectional diagrams illustrating a method of cleaning a semiconductor substrate in accordance with a preferred embodiment of the present invention; and

FIG. 9 is a schematic flow chart illustrating a method of cleaning a semiconductor substrate in accordance with the preferred embodiment of the present invention.

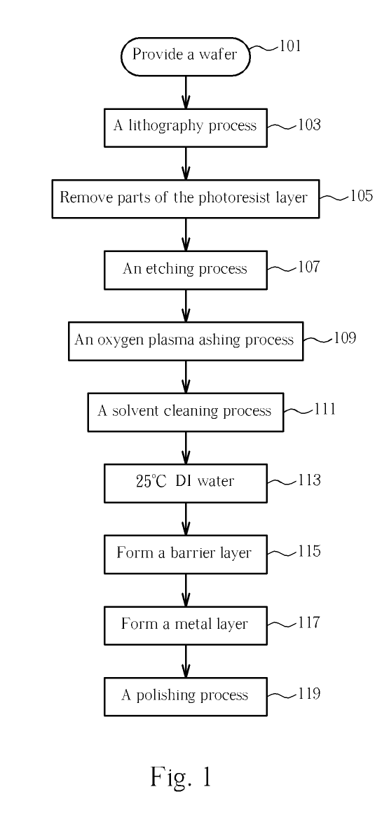

### DETAILED DESCRIPTION

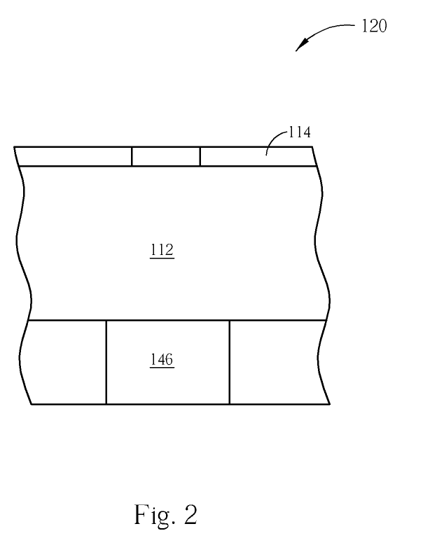

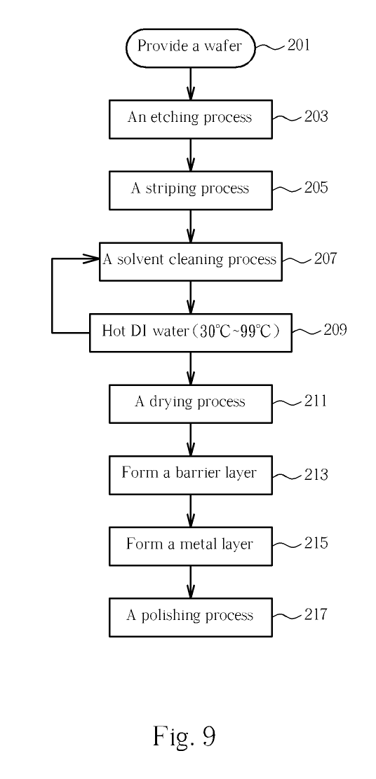

Please refer to FIGS. 2-9. FIGS. 2-8 are a plurality of schematic cross-sectional diagrams illustrating a method of cleaning a semiconductor substrate in accordance with a preferred embodiment of the present invention, and FIG. 9 is a schematic flow chart illustrating a method of cleaning a semiconductor substrate in accordance with the preferred embodiment of the present invention, where like number numerals designate similar or the same parts, regions or elements. It is to be understood that the drawings are not drawn to scale, and are used only for illustration purposes.

First, as shown in FIG. 2 and in the step 201 of FIG. 9, a semiconductor substrate 120 is first provided, the semiconductor substrate 120 includes a conductor 146, a dielectric material layer 112, and a patterned photoresist layer 114. As known to those skilled in the art, a predetermined material layer of the wafer is required to be coated with a photoresist film when a pattern can be transferred and formed on the photoresist film through the images projected onto the photoresist film. A baking process and a lithography process can be subsequently performed to remove the unexposed parts of the photoresist film for forming the above-mentioned patterned photoresist layer 114. In general, the semiconductor substrate 120 can be made from semiconductor materials, such as a silicon substrate, a silicon-containing substrate, or silicon-on-insulator (SOI). For instance, the semiconductor substrate 120 can be in the form of a wafer. The dielectric material layer 112 can be made of silicon oxide, or doped silicon oxide comprising phosphosilicate glass (PSG) or borophosposilicate glass (BPSG), or other similar insulating materials. The patterned photoresist layer 114 can include positive photoresist material or negative photoresist material. The conductor 146 can be any conductive substance or a conducting region inside a semiconductor device. For example, the conductor 146 can be a part of a metal circuit, a conducting plug, a source region of a metal-oxide-semiconductor (MOS) device, a drain region of a MOS device, a gate of a MOS device, or a connecting region of a diode. It should be noted that, the above-mentioned dielectric material layer 112 could be replaced by other material layers which are not dielectric materials, such as an aluminum layer or an aluminum alloy passivation layer.

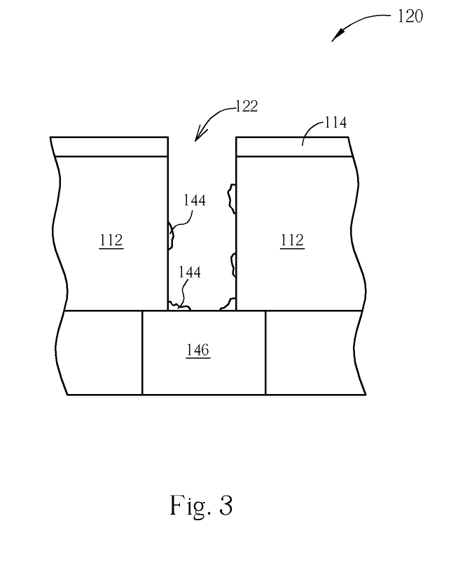

Next, as shown in FIG. 3 and in the step 203 of FIG. 9, an etching process, such as a plasma etching process or a reactive ion etching process, is carried out on the semiconductor substrate 120 so that the pattern of the patterned photoresist layer 114 is transferred to the underlying dielectric material layer 112. Thus, an etched hole 122, such as a contact plug hole, a via plug hole, or a trench, can be formed in the dielectric material layer 112, as well as exposing the conductor 146.

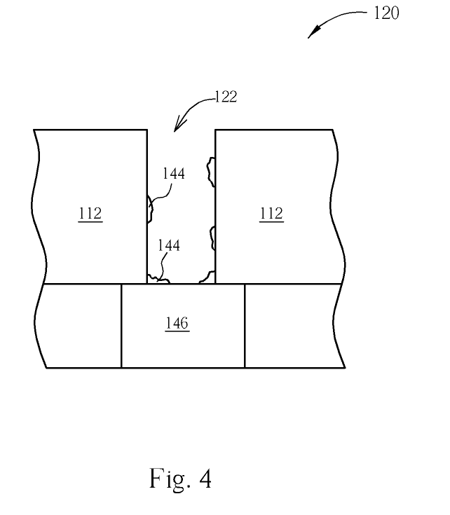

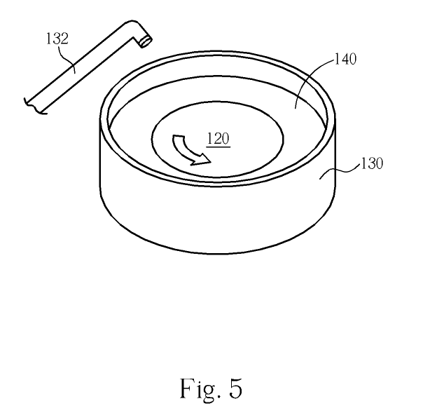

Thereafter, as shown in FIG. 4 and in the step 205 of FIG. 9, a striping process, such as an oxygen plasma ashing process or a wet chemical etching process, is performed to strip the patterned photoresist layer 114. Afterwards, the semiconductor substrate 120 may be transferred to a semiconductor chemical wet station for removing a plurality of residues and polymers 144 disposed on the surface of the semiconductor substrate 120. As shown in FIG. 5 and in the step 207 of FIG. 9, a solvent cleaning process is next performed in the semiconductor chemical wet station, and the semiconductor substrate 120 is rotated and immersed inside a tank 130. A cleaning solvent 140 at high temperature, such as a hydroxylamine-containing solvent at 70° C., is injected inside the tank 130 for removing the residues and polymers 144 disposed on the surface of the dielectric material layer 112, on the sidewall of the plug hole 122, and on the bottom of the plug hole 122. The semiconductor substrate 120 is usually immersed inside the cleaning solvent 140 for about 5-30 minutes, such as, for example, 10 minutes. Next, a spin-drying process is carried out on the semiconductor substrate 120. Most of the cleaning solvent 140 disposed on the semiconductor substrate 120 are therefore removed due to inertia and the centrifugal force.

The cleaning solvent 140 can be an amine-base solvent or a fluoride-base solvent, such as EKC-270™ or ACT-935. According to this preferred embodiment, the cleaning solvent 140 contained inside the tank 130 contains EKC-270™. The EKC-270™ cleaning solvent is a commercial post-etch residue remover from EKC Technology, Inc of DuPont™, and is formulated to remove ashed photoresist residue, organic polymer, and organicmetallic etch residue located on the surface of the semiconductor substrate. The EKC-270™ cleaning solvent mainly contains hydroxylamine. The ACT-935 cleaning solvent is also a commercial post-etch residue remover made by Ashland, and mainly contains monoethanolamine (MEA) and hydroxylamine.

The cleaning solvent 140 is usually flows into the tank 130 through a cleaning solvent control valve (not shown in the drawing) and a tube 132. A pump for transferring liquid (not shown in the drawing) can be connected to the tube 132. In addition, the cleaning solvent 140 can be contained in a containing tank (not shown in the drawing) before the cleaning solvent 140 flows into the tank 130. The containing tank includes a heater for heating the cleaning solvent 140 to a proper process temperature. For example, the boiling point of the EKC-270™ cleaning solvent is in a range between 110° C. to 170° C., so the temperature of the EKC-270™ cleaning solvent should not be higher than 110° C. The actual process temperature can be adjusted according to the parameters, such as the materials of the semiconductor substrate 120 and the process condition of the solvent cleaning process. On one hand, the cleaning solvent should have the ability of removing the by-products effectively. On the other hand, the underlying conductor 146 should not be corroded by the cleaning solvent.

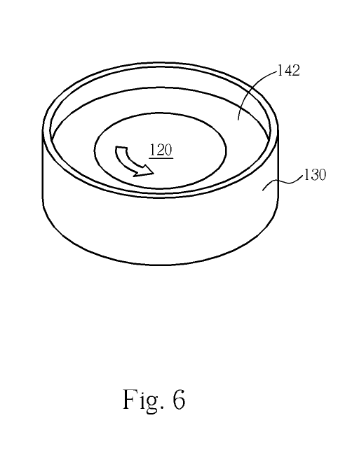

Next, as shown in FIG. 6 and in the step 209 of FIG. 9, a water cleaning process is performed on the semiconductor substrate 120 by utilizing a deionized water 142 so as to remove the cleaning solvent 140 disposed on the dielectric material layer 112. The temperature of the deionized water 142 utilized in the water cleaning process is in a range from 30° C. to 99° C., such as 70° C., and the reaction time of the water cleaning process is in the range from 30 seconds to 5 minutes, such as 1 minute. The cleaning solvent 140 remained on the surface of the semiconductor substrate 120, on the sidewall of the plug hole 122, and on the bottom of the plug hole 122 can be heated by the deionized water 142 and dissolves in the deionized water 142. Therefore, the viscosity of the cleaning solvent 140 can be decreased, and it is easier to remove the cleaning solvent 140 from the surface of the semiconductor substrate 120. In addition, since the water cleaning process takes less time to remove the cleaning solvent 140, the conductor 146 is protected from over-etching.

On the other hand, due to the higher temperature of the deionized water 142, hydrolysis reaction is easier hydrolyze occurred between the deionized water 142 and components of the cleaning solvent 140 so the cleaning solvent 140 is easier removed by the deionized water 142. Furthermore, the by-products, which are formed from the reaction between the deionized water 142 and the cleaning solvent 140, can help the water cleaning process to remove oxide and polymers disposed on the surface of the semiconductor substrate 120. For example, when the cleaning solvent 140 contains EKC-270™, ammonium hydroxide can be formed from the reaction between the deionized water 142 and hydroxylamine, and ammonium hydroxide can help the water cleaning process to remove oxide and polymers.

The said step 207 and step 209 can be carried out alternatively and repeatedly. In other words, the solvent cleaning process and the water cleaning process can be a multi-cycle. Therefore, after the above-mentioned water cleaning process, the semiconductor substrate 120 can undergo the solvent cleaning process and the water cleaning process repeatedly until the residues, the polymers 144 and the cleaning solvent 140 are removed.

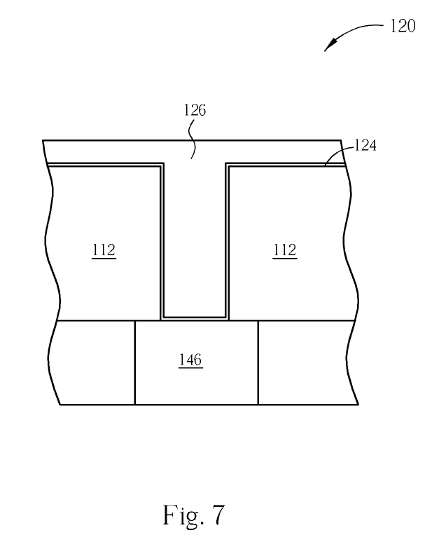

Thereafter, as shown in the step 211of FIG. 9,120 a drying process is carried out on the semiconductor substrate. For instance, the semiconductor substrate 120 can be dried by nitrogen gas in the drying process. Next, as shown in FIG. 7, in the step 213 and in the step 215 of FIG. 9, a glue layer or a barrier layer 124 is formed on the surface of the semiconductor substrate 120, and covers the surface of the dielectric material layer 112, the sidewall of the plug hole 122, and the bottom of the plug hole 122. Afterward, a conductive layer 126 is formed on the surface of the barrier layer 124, and the etched hole 122 is filled with the conductive layer 126. The conductive layer 126 is made of a metal material or compound comprising tungsten (W), titanium nitride (TiN), and titanium tungsten (TiW), etc.

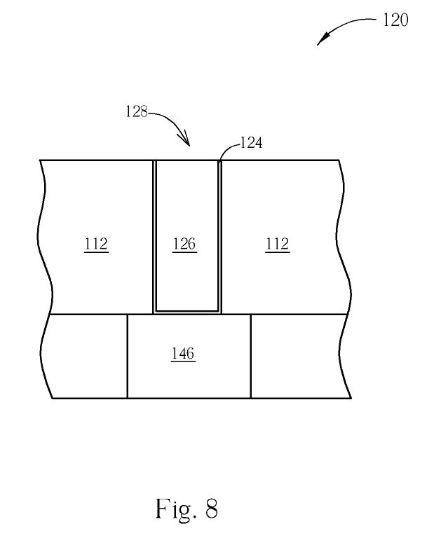

Afterward, as shown in FIG. 8 and in the step 217 of FIG. 9, a planarity process, such as a chemical mechanical polishing (CMP) process, is performed to remove the unnecessary part of the barrier layer 124 and the unnecessary part of the conductive layer 126. Accordingly, a plug 128, such as a contact plug or a via plug, can be formed in the dielectric material layer 112.

In anther embodiment of the present invention, a pre-water washing process can be further included before the solvent cleaning process. The pre-water washing process is also performed on the semiconductor substrate 120 by utilizing a deionized water 142 at high temperature. The water cleaning process, the solvent cleaning process and the pre-water washing process can be carried out in a single process apparatus or in different process apparatuses. Additionally, the water cleaning process, the solvent cleaning process and the pre-water washing process can be performed through a single process tool or through different process tools. For example, the water cleaning process, the solvent cleaning process and the pre-water washing process can all be performed in one semiconductor chemical wet station, and the process tools, such as a solvent cleaning tool or a scrubber cleaning tool, can be utilized.

The solvent cleaning process can be performed immediately after the pre-water washing process, and the water cleaning process can be performed immediately after the solvent cleaning process. In other words, there can be no process between the solvent cleaning process and the pre-water washing process, or between the water cleaning process and the solvent cleaning process. Furthermore, additional steps, such as an intermediate post-solvent rinse (IPR) step or a scrubbing step, can be carried out between the solvent cleaning process and the pre-water washing process, or between the water cleaning process and the solvent cleaning process according to the process design.

A plug structure is formed in the above-mentioned embodiment for illustrating the present invention. However, it should be understood by a person skilled in this art that the present invention is characterized by using the deionized water at high temperature to remove the cleaning solvent and the residues on the semiconductor substrate, so the present invention should not be limited to a plug structure. The present invention can be applied for forming or cleaning a metal connection structure or a pad structure. For example, the dielectric material layer 112 in the above-mentioned embodiment can be replaced by another material layer, such as an aluminum layer. The patterned photoresist layer 114 can having any pattern, and the patterned photoresist layer 114 can be replaced by a patterned hard mask having other material, such as a patterned hard mask containing oxynitride. In other words, present invention can be applied to a cleaning process after any etching process, or to a cleaning process before any deposition process.

Since the present invention utilizes a deionized water at high temperature to remove the residues disposed on the semiconductor substrate, there are some advantages for the present invention as following listed. First, because the deionized water at high temperature can effectively remove the cleaning solvent and the residues disposed on the semiconductor substrate, the yield of products fabricated by the method of the present invention is greatly increased, the variations in yield from apparatus to apparatus are decreased, and the stability of process is promoted. Subsequently, since the cleaning solvent can be effectively removed, the period of exchanging the cleaning solvent can be increased. In other words, it is unnecessary for the cleaning solvent to be exchanged every 8 hours. Accordingly, the process time and the cost of exchanging the cleaning solvent can both be saved, and the productivity is increased. Furthermore, because the product yield is increased and the variations in yield are decreased, the permitted variations in process parameters for different apparatuses can be extended. That is to say, a kind of processes can be easily performed by a plurality of apparatuses, and the products fabricated by the different apparatuses will not be uneven.

Those skilled in the art will readily observe that numerous modifications and alterations of the device and method may be made while retaining the teachings of the invention.

What is claimed is:

1. A method of cleaning a semiconductor substrate, comprising:
providing a semiconductor substrate, the semiconductor substrate comprising a material layer and a patterned photoresist layer disposed on the material layer;
etching the material layer by utilizing the patterned photoresist layer as an etching mask for forming an etched hole in the material layer;
performing a solvent cleaning process on the semiconductor substrate by utilizing a cleaning solvent; and
performing a water cleaning process on the semiconductor substrate by utilizing the deionized water (D1 water), and a temperature of the deionized water is in the range from 30° C. to 99° C.

2. The method of claim 1, wherein a reaction time of the water cleaning process is in the range from 30 seconds to 5 minutes.

3. The method of claim 1, wherein the solvent cleaning process and the water cleaning process are a multi-cycle.

4. The method of claim 1, wherein the cleaning solvent comprises hydroxylamine.

5. The method of claim 1, wherein a temperature of the cleaning solvent is lower than 110° C.

6. The method of claim 1, wherein the material layer comprises a dielectric material layer.

7. The method of claim 1, wherein the etched hole comprises a contact plug hole or a via plug hole.

8. The method of claim 1, further comprising a step of spin-drying the semiconductor substrate after the solvent cleaning process.

9. The method of claim 1, further comprising a step of performing a drying process on the semiconductor substrate after the water cleaning process.

10. The method of claim 9, wherein the semiconductor substrate is dried by using nitrogen gas in the drying process.

11. The method of claim 1, further comprising a step of removing the patterned photoresist layer before the solvent cleaning process.

12. The method of claim 1, wherein the solvent cleaning process and the water cleaning process are performed in a single apparatus.

13. The method of claim 1, wherein the solvent cleaning process and the water cleaning process are performed in different apparatuses.

14. The method of claim 1, further comprising a step of performing a pre-water washing process on the semiconductor substrate by utilizing the deionized water before the solvent cleaning process.

15. The method of claim 14, wherein the solvent cleaning process and the pre-water washing process are performed in a single apparatus.

16. The method of claim 14, wherein the solvent cleaning process and the pre-water washing process are performed in different apparatuses.

17. A method of cleaning a semiconductor substrate, comprising:
providing a semiconductor substrate, the semiconductor substrate comprising a material layer;
performing a solvent cleaning process on the semiconductor substrate and the material layer by utilizing a cleaning solvent, the cleaning solvent comprising hydroxylamine; and
performing a water cleaning process on the semiconductor substrate by utilizing the deionized water, and a temperature of the deionized water is in the range from 30° C. to 99° C.

18. The method of claim 17, wherein a reaction time of the water cleaning process is in the range from 30 seconds to 5 minutes.

19. The method of claim 17, wherein the solvent cleaning process and the water cleaning process are a multi-cycle.

20. The method of claim 17, further comprising a step of spinning the semiconductor substrate after the solvent cleaning process.

21. The method of claim 17, further comprising a step of performing a drying process on the semiconductor substrate after the water cleaning process.
